(19) United States
(12) Patent Application Publication
(10) Pub. No.: US 2025/0151232 A1
(43) Pub. Date: May 8, 2025

(54) POWER CONVERTER WITH INTEGRATED HEAT PIPE

(71) Applicant: VERTIV CORPORATION, Westerville, OH (US)

(72) Inventors: AKSHAY SHAH, Pune (IN); VINAYAK BHAT, Pune (IN)

(73) Assignee: VERTIV CORPORATION, Westerville, OH (US)

(21) Appl. No.: 18/942,154

(22) Filed: Nov. 8, 2024

(30) Foreign Application Priority Data
Nov. 8, 2023 (IN) 202321076243

(51) Int. Cl. H05K 7/20

(52) U.S. Cl. CPC H05K 7/20336; H05K 7/209

(57) ABSTRACT

A power supply system can include a case, a plurality of sets of power converter connections within the case, and a plurality of power converters configured to be removably coupled to corresponding ones of the sets of connections. A power converter can include a housing, a plurality of power connectors configured to be removably coupled to corresponding ones of the connections, a plurality of heat generating devices within the housing, an external heat sink, and a heat pipe that thermally couples the heat generating devices to the external heat sink.

### CROSS REFERENCE TO RELATED APPLICATIONS

This application claims the benefit of Indian Patent Application number 202321076243 filed Nov. 8, 2023, the entire contents of which are incorporated herein by reference.

### TECHNICAL FIELD

The present disclosure relates generally to power converters and more specifically relates to cooling systems for power converters.

### BACKGROUND

Power converters, such as AC-to-DC and/or DC-to-DC converters, produce heat. In densely packed arrangements, where two or more power converters are located close together, this heat is additive and can be challenging to transfer from such closely located power converters.

### SUMMARY

Applicant has created new and useful devices, systems and methods for cooling power converters. In at least one embodiment, a power converter according the disclosure can include one or more heat pipes for extracting heat from internal components, such as inductors and/or semi-conductors, and can transfer that heat to one or more external heat sinks for more efficiently extracting heat produced within the power converter and/or allowing more power to be drawn from the power converter.

In at least one embodiment, a power supply system can include a case, a plurality of sets of power converter connections within the case, a plurality of power converters removably coupled to the connections, or any combination thereof. In at least one embodiment, each set of connections can include an input connection connected to a power source and an output connection connected to a power load. In at least one embodiment, the power source can supply power at a first voltage and the power load can receive power at a second voltage. In at least one embodiment, the first voltage can be different than the second voltage.

In at least one embodiment, each power converter can include a housing, a plurality of power connectors removably couplable to the connections, a plurality of heat generating devices within the housing, an external heat sink mounted to the housing, a heat pipe thermally coupling the heat generating devices within the housing to the external heat sink, or any combination thereof. In at least one embodiment, the plurality of heat generating devices can include at least one inductor and/or at least one semiconductor. In at least one embodiment, the heat pipe can be directly thermally coupled to the semiconductor and/or the inductor.

In at least one embodiment, each power converter can include an inductor heat sink thermally coupled with the inductor. In at least one embodiment, the heat pipe can be indirectly thermally coupled to the inductor through the inductor heat sink. In at least one embodiment, each power converter can include a semiconductor heat sink thermally coupled with the semiconductor. In at least one embodiment, the heat pipe can be indirectly thermally coupled to the semiconductor through the semiconductor heat sink.

In at least one embodiment, each power converter can include a printed circuit board within the housing. In at least one embodiment, the inductor and/or the semiconductor can be mounted to the printed circuit board. In at least one embodiment, the heat pipe can be directly thermally coupled to the printed circuit board.

In at least one embodiment, the external heat sink can be mounted to a top of the housing or a bottom of the housing. In at least one embodiment, the external heat sink can be mounted to a front of the housing. In at least one embodiment, the front of the housing can be opposite a back of the housing. In at least one embodiment, the connectors can extend from the back of the housing and electrically couple the power converter to the power source and/or the power load. In at least one embodiment, the external heat sink can be mounted directly to the housing without a bracket therebetween. In at least one embodiment, the external heat sink can be indirectly mounted to the housing through a bracket. In at least one embodiment, the external heat sink can extend through the housing or be located wholly outside the housing.

In at least one embodiment, each power converter can include a printed circuit board within the housing. In at least one embodiment, the printed circuit board can be aligned along a vertical plane when the power converter is coupled to the connections. In at least one embodiment, the external heat sink can be mounted above the printed circuit board or below the printed circuit board. In at least one embodiment, the external heat sink can be mounted to the housing distal from the connections. In at least one embodiment, the external heat sink can be thermally coupled to the printed circuit board.

### BRIEF DESCRIPTION OF THE DRAWINGS

FIG. 1 is a perspective view of one of many embodiments of a power supply system according to the disclosure.

FIG. 2 is a perspective view of one of many embodiments of a power converter according to the disclosure.

FIG. 3 is a perspective view of one of many embodiments of a heat sink according to the disclosure.

FIG. 4 is a perspective view of one of many embodiments of a heat pipe according to the disclosure.

FIG. 5 is a perspective view of another one of many embodiments of a power converter according to the disclosure.

FIG. 6 is a perspective view of yet another of many embodiments of a power converter according to the disclosure.

FIG. 7 is an elevation view of yet another one of many embodiments of a power converter according to the disclosure.

FIG. 8 is a perspective view of the power converter of FIG. 7.

FIG. 9 is a perspective view of one of many embodiments of a portion of a power converter according to the disclosure.

FIG. 10 is a perspective view of one of many embodiments of a heat sink according to the disclosure.

### DETAILED DESCRIPTION

The figures described above and the written description of specific structures and functions below are not presented to limit the scope of what Applicants has invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms.

The use of a singular term, such as, but not limited to, “a,” is not intended as limiting of the number of items. Also, the use of relational terms, such as, but not limited to, “top,” “bottom,” “left,” “right,” “upper,” “lower,” “down,” “up,” “side,” and the like are used in the written description for clarity in specific reference to the figures and are not intended to limit the scope of the inventions or the appended claims. The terms “including” and “such as” are illustrative and not limitative. The terms “couple,” “coupled,” “coupling,” “coupler,” and like terms are used broadly herein and can include any method or device for securing, binding, bonding, fastening, attaching, joining, inserting therein, forming thereon or therein, communicating, or otherwise associating, for example, mechanically, magnetically, electrically, chemically, operably, directly or indirectly with intermediate elements, one or more pieces of members together and can further include without limitation integrally forming one functional member with another in a unity fashion. The coupling can occur in any direction, including rotationally. Further, all parts and components of the disclosure that are capable of being physically embodied inherently include imaginary and real characteristics regardless of whether such characteristics are expressly described herein, including but not limited to characteristics such as axes, ends, inner and outer surfaces, interior spaces, tops, bottoms, sides, boundaries, dimensions (e.g., height, length, width, thickness), mass, weight, volume and density, among others.

Applicant has created new and useful devices, systems and methods for power converter cooling systems. In at least one embodiment, power converters according the disclosure can include one or more heat pipes to extract heat from internal components, such as inductors and/or semi-conductors, and transfer that heat to one or more externally mounted heat sinks, thereby more efficiently extracting heat produced within the power converter and/or allowing more power to be drawn from the power converter.

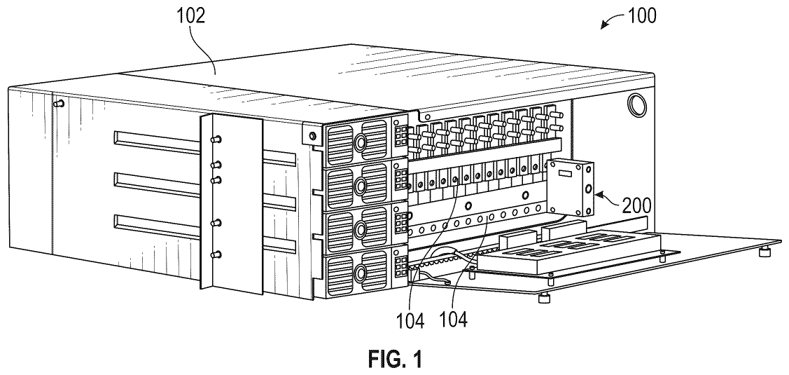

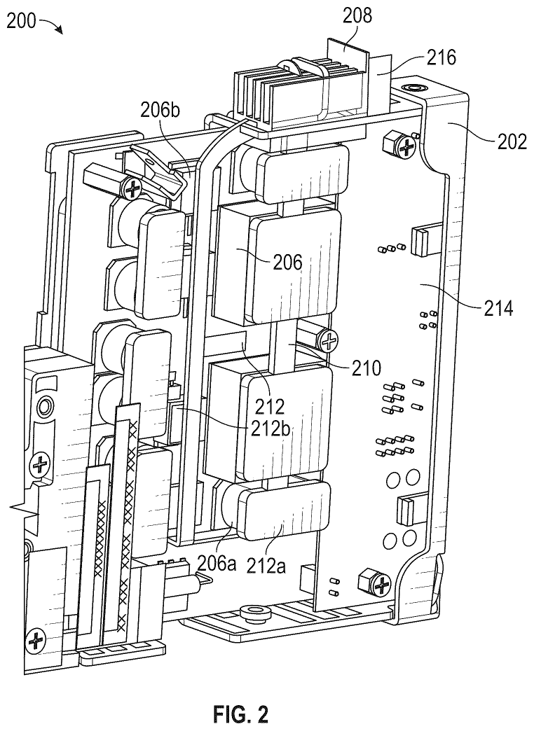

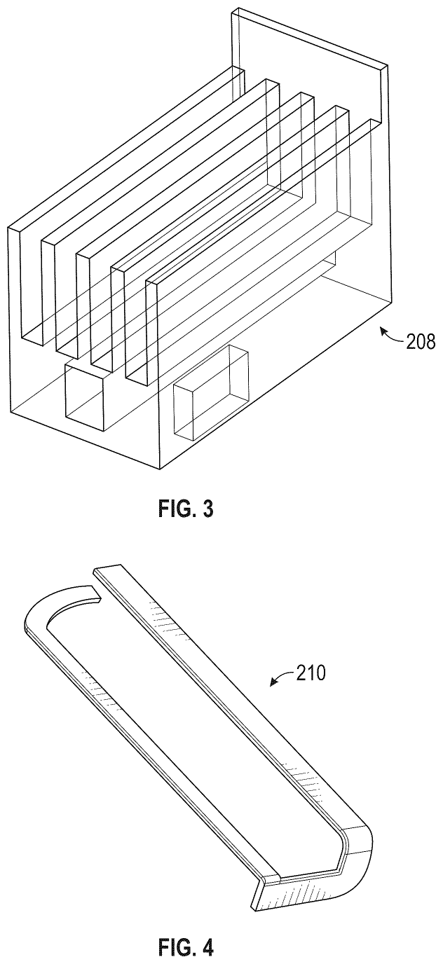

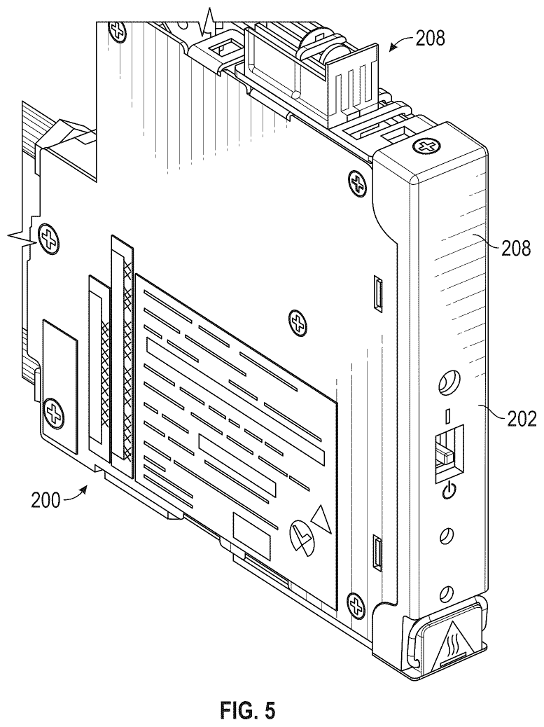

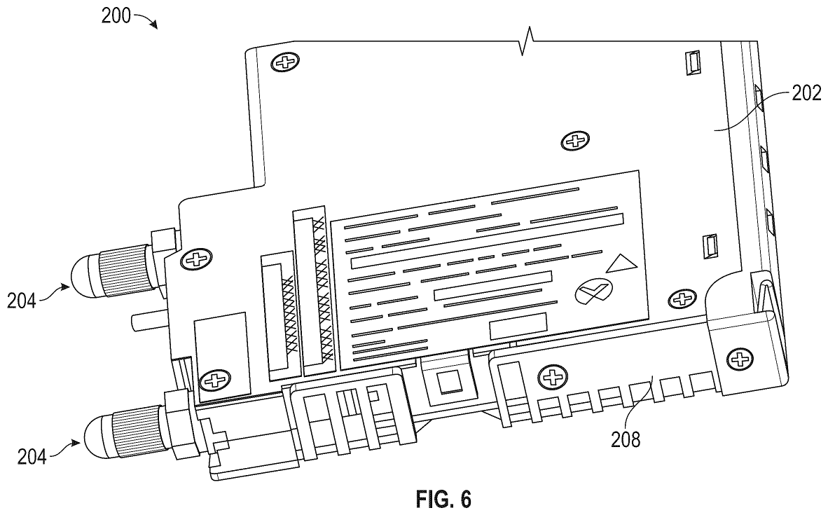

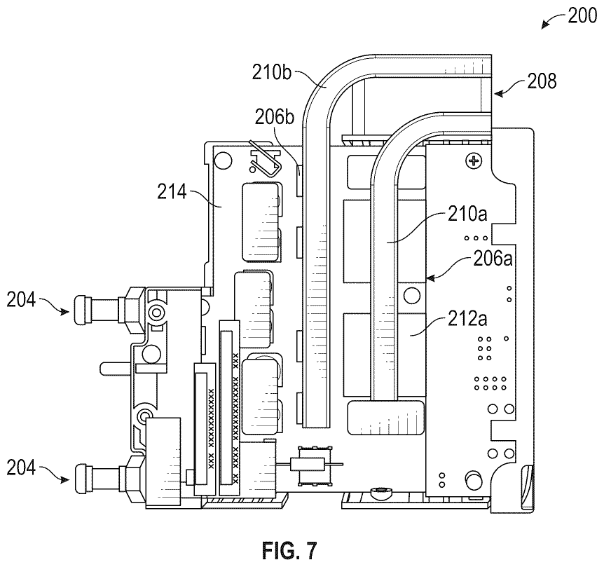

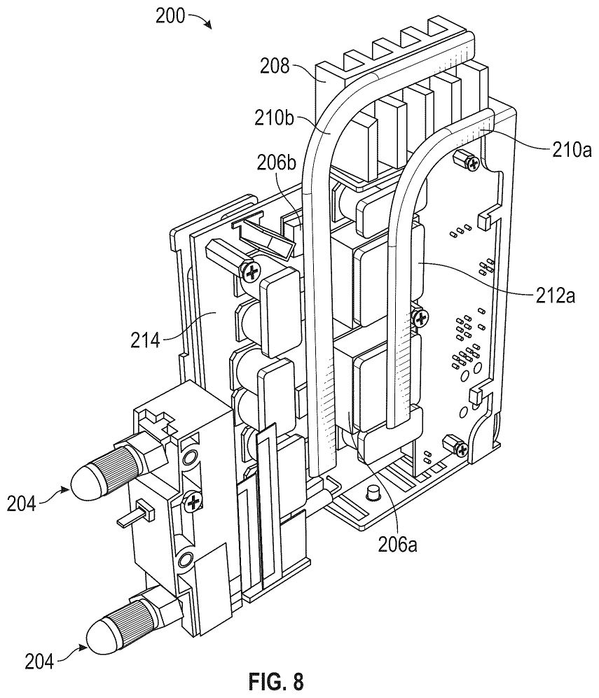

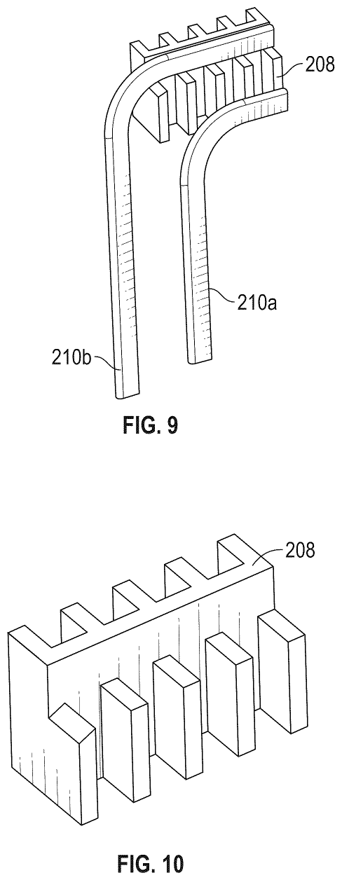

FIG. 1 is a perspective view of one of many embodiments of a power supply system according to the disclosure. FIG. 2 is a perspective view of one of many embodiments of a power converter according to the disclosure. FIG. 3 is a perspective view of one of many embodiments of a heat sink according to the disclosure. FIG. 4 is a perspective view of one of many embodiments of a heat pipe according to the disclosure. FIG. 5 is a perspective view of another one of many embodiments of a power converter according to the disclosure. FIG. 6 is a perspective view of yet another of many embodiments of a power converter according to the disclosure. FIG. 7 is an elevation view of yet another one of many embodiments of a power converter according to the disclosure. FIG. 8 is a perspective view of the power converter of FIG. 7. FIG. 9 is a perspective view of one of many embodiments of a portion of a power converter according to the disclosure. FIG. 10 is a perspective view of one of many embodiments of a heat sink according to the disclosure. FIGS. 1-10 are described in conjunction with one another.

In at least one embodiment, a power supply system 100 according to the disclosure can include one or more cases 102, a plurality of sets of power converter connections 104 within the case 102, a plurality of power converters 200 removably coupled to the connections 104, or any combination thereof. In at least one embodiment, each set of connections 104 can include an input connection 104 connected to a power source and an output connection 104 connected to a power load. In at least one embodiment, the power source can supply power at a first voltage and the power load can receive power at a second voltage. In at least one embodiment, the first voltage can be different than the second voltage. In at least one embodiment, power supply system 100 and/or the power converters 200 can be or include one or more of those currently sold by Vertiv Corporation, such as under the NetSure™ brand, or the like.

In at least one embodiment, each power converter 200 can be removably mounted within the case 102. In at least one embodiment, each power converter 200 can include one or more housings 202, a plurality of power connectors 204 removably couplable to the connections 104, a plurality of heat generating devices 206 within the housing 202, one or more external heat sinks 208 mounted to the housing 202, one or more a heat pipes 210 thermally coupling the heat generating devices 206 within the housing 202 to one or more of the external heat sinks 208, or any combination thereof. In at least one embodiment, the plurality of heat generating devices 206 can include one or more inductors 206a and/or one or more semiconductors 206b. In at least one embodiment, the heat pipe 210 can be directly thermally coupled to the semiconductor 206b and/or the inductor 206a.

In at least one embodiment, each power converter 200 can include one or more internal heat sinks 212a thermally coupled with the inductor 206a. In at least one embodiment, the heat pipe 210 can be indirectly thermally coupled to the inductor 206a through the internal heat sink 212a. In at least one embodiment, each power converter 200 can include one or more internal heat sinks 212b thermally coupled with the semiconductor 206b. In at least one embodiment, the heat pipe 210 can be indirectly thermally coupled to the semiconductor 206b through the internal heat sink 212b.

In at least one embodiment, a first heat pipe 210a can be directly thermally coupled to the inductor(s) 206a and/or a second heat pipe 210b can be directly thermally coupled to the semiconductor(s) 206b. In at least one embodiment, a first heat pipe 210a can be thermally coupled to the inductor(s) 206a through the internal heat sink 212a and/or a second heat pipe 210b can be directly thermally coupled to the semiconductor(s) 206b through the internal heat sink 212b. In at least one embodiment, a first heat pipe 210a can be directly thermally coupled to the inductor(s) 206a and/or a second heat pipe 210b can be directly thermally coupled to the semiconductor(s) 206b through the internal heat sink 212b. In at least one embodiment, a first heat pipe 210a can be thermally coupled to the inductor(s) 206a through the internal heat sink 212a and/or a second heat pipe 210b can be directly thermally coupled to the semiconductor(s) 206b.

In at least one embodiment, each power converter 200 can include one or more printed circuit boards 214 within the housing 202. In at least one embodiment, the inductor 206a and/or the semiconductor 206b can be mounted to the printed circuit board 214. In at least one embodiment, the heat pipe 210 can be directly thermally coupled to the printed circuit board 214.

In at least one embodiment, one or more external heat sinks 208 can be mounted to a top of the housing 202. In at least one embodiment, one or more external heat sinks 208 can be mounted to a bottom of the housing 202. In at least one embodiment, one or more external heat sinks 208 can be mounted to a front of the housing 202. In at least one embodiment, the front of the housing 202 can be opposite a back of the housing 202. In at least one embodiment, the connectors 204 can extend from the back of the housing 202 and electrically couple the power converter 200 to the power source and/or the power load. In at least one embodiment, the external heat sink 208 can be mounted directly to the housing 202 without a bracket therebetween. In at least one embodiment, the external heat sink 208 can be indirectly mounted to the housing 202 through a bracket 216. In at least one embodiment, the external heat sink 208 can extend through the housing 202 or be located wholly outside the housing 202.

In at least one embodiment, the printed circuit board 214 can be aligned along a vertical plane when the power converter 202 is coupled to the connections 104. In at least one embodiment, one or more external heat sinks 208 can be mounted above the printed circuit board 214. In at least one embodiment, one or more external heat sinks 208 can be mounted below the printed circuit board 214. In at least one embodiment, one or more external heat sinks 208 can be mounted to the housing 202 distal from the connections 104 and/or connectors 204. In at least one embodiment, one or more external heat sinks 208 can be thermally coupled to the printed circuit board 214.

In at least one embodiment, one or more internal heat sinks 212 can be thermally coupled to the printed circuit board 214. In at least one embodiment, the heat pipe 210 can be indirectly thermally coupled to the printed circuit board 214 through the internal heat sink 212.

In at least one embodiment, a power supply system can include a case, a plurality of sets of power converter connections within the case, a plurality of power converters removably coupled to the connections, or any combination thereof. In at least one embodiment, each set of connections can include an input connection connected to a power source and an output connection connected to a power load. In at least one embodiment, the power source can supply power at a first voltage and the power load can receive power at a second voltage. In at least one embodiment, the first voltage can be different than the second voltage.

In at least one embodiment, each power converter can include a housing, a plurality of power connectors removably couplable to the connections, a plurality of heat generating devices within the housing, an external heat sink mounted to the housing, a heat pipe thermally coupling the heat generating devices within the housing to the external heat sink, or any combination thereof. In at least one embodiment, the plurality of heat generating devices can include at least one inductor and/or at least one semiconductor. In at least one embodiment, the heat pipe can be directly thermally coupled to the semiconductor and/or the inductor.

In at least one embodiment, each power converter can include an inductor heat sink thermally coupled with the inductor. In at least one embodiment, the heat pipe can be indirectly thermally coupled to the inductor through the inductor heat sink. In at least one embodiment, each power converter can include a semiconductor heat sink thermally coupled with the semiconductor. In at least one embodiment, the heat pipe can be indirectly thermally coupled to the semiconductor through the semiconductor heat sink.

In at least one embodiment, each power converter can include a printed circuit board within the housing. In at least one embodiment, the inductor and the semiconductor can be mounted to the printed circuit board. In at least one embodiment, the heat pipe can be directly thermally coupled to the printed circuit board.

In at least one embodiment, the external heat sink can be mounted to a top of the housing or a bottom of the housing. In at least one embodiment, the external heat sink can be mounted to a front of the housing. In at least one embodiment, the front of the housing can be opposite a back of the housing. In at least one embodiment, the connectors can extend from the back of the housing and electrically couple the power converter to the power source and/or the power load. In at least one embodiment, the external heat sink can be mounted directly to the housing without a bracket therebetween. In at least one embodiment, the external heat sink can be indirectly mounted to the housing through a bracket. In at least one embodiment, the external heat sink can extend through the housing or be located wholly outside the housing.

In at least one embodiment, each power converter can include a printed circuit board within the housing. In at least one embodiment, the printed circuit board can be aligned along a vertical plane when the power converter is coupled to the connections. In at least one embodiment, the external heat sink can be mounted above the printed circuit board or below the printed circuit board. In at least one embodiment, the external heat sink can be mounted to the housing distal from the connections. In at least one embodiment, the external heat sink can be thermally coupled to the printed circuit board.

Other and further embodiments utilizing one or more aspects of the disclosure can be devised without departing from the spirit of Applicant's disclosure. For example, the devices, systems and methods can be implemented for numerous different types and sizes in numerous different industries. Further, the various methods and embodiments of the devices, systems and methods can be included in combination with each other to produce variations of the disclosed methods and embodiments. Discussion of singular elements can include plural elements and vice versa. The order of steps can occur in a variety of sequences unless otherwise specifically limited. The various steps described herein can be combined with other steps, interlineated with the stated steps, and/or split into multiple steps. Similarly, elements have been described functionally and can be embodied as separate components or can be combined into components having multiple functions.

The inventions have been described in the context of preferred and other embodiments and not every embodiment of the inventions has been described. Obvious modifications and alterations to the described embodiments are available to those of ordinary skill in the art having the benefits of the present disclosure. The disclosed and undisclosed embodiments are not intended to limit or restrict the scope or applicability of the inventions conceived of by the Applicant, but rather, in conformity with the patent laws, Applicant intends to fully protect all such modifications and improvements that come within the scope or range of equivalents of the following claims.

What is claimed is:

1. A power supply system comprising:
a case;
a plurality of sets of power converter connections within the case, wherein each set of connections includes an input connection configured to be connected to a power source and an output connection configured to be connected to a power load; and
a plurality of power converters, each power converter configured to be removably coupled to one set of connections, wherein each power converter comprises a housing;
a plurality of power connectors configured to be removably coupled to corresponding ones of the connections;
a plurality of heat generating devices within the housing;
an external heat sink mounted to the housing; and
a heat pipe thermally coupling the heat generating devices within the housing to the external heat sink mounted to the housing.

2. The system of claim 1, wherein the plurality of heat generating devices further comprises at least one inductor and at least one semiconductor.

3. The system of claim 2, further comprising an inductor heat sink thermally coupled with the at least one inductor.

4. The system of claim 3, wherein the heat pipe is directly thermally coupled to the at least one semiconductor and indirectly thermally coupled to the at least one inductor through the inductor heat sink.

5. The system of claim 2, further comprising a printed circuit board within the housing, wherein the at least one inductor and the at least one semiconductor are mounted to the printed circuit board, and wherein the heat pipe is directly thermally coupled to the printed circuit board.

6. The system of claim 1, wherein the external heat sink is mounted to a top of the housing.

7. The system of claim 1, wherein the external heat sink is mounted to a bottom of the housing.

8. The system of claim 1, wherein the external heat sink is mounted to a front of the housing.

9. The system of claim 8, wherein the front of the housing is opposite a back of the housing, wherein the connectors extend from the back of the housing and electrically couple the power converter to the power source supplying power at a first voltage and the power load receiving power at a second voltage, and wherein the first voltage is different than the second voltage.

10. The system of claim 1, wherein the external heat sink is mounted directly to the housing.

11. The system of claim 1, wherein the external heat sink is indirectly mounted to the housing via a bracket.

12. The system of claim 1, further comprising a printed circuit board within the housing, wherein the printed circuit board is aligned along a vertical plane when the power converter is coupled to the connections.

13. The system of claim 12, wherein the external heat sink is mounted above the printed circuit board.

14. The system of claim 12, wherein the external heat sink is mounted below the printed circuit board.

15. The system of claim 12, wherein the external heat sink is mounted to the housing distal from the connections.

16. The system of claim 12, wherein the external heat sink is thermally coupled to the printed circuit board.

17. The system of claim 1, wherein the external heat sink extends through the housing.

18. The system of claim 1, wherein the external heat sink is located wholly outside the housing.
